(19) United States
(12) Patent Application Publication
(10) Pub. No.: US 2026/0072360 A1
(43) Pub. Date: Mar. 12, 2026

(54) AUTOMATED MODEL TERM SELECTION FOR MONITORING AND OPTIMIZED PROCESS CONTROL

(71) Applicant: KLA Corporation, Milpitas, CA (US)

(72) Inventors: Christoph Ehrlich, Dresden (DE); Philip Groeger, Dresden (DE)

(21) Appl. No.: 18/828,398

(22) Filed: Sep. 9, 2024

(51) Int. Cl. G03F 7/00

(52) U.S. Cl. CPC G03F 7/706839; G03F 7/70625; G03F 7/70633

(57) ABSTRACT

Automated model term selection may use lasso regression for selecting model terms and a cross-validation scheme to optimize a regularization parameter of the lasso regression. A value of the regularization parameter may be selected by cross-validating the regularization parameter across a range of possible values using metrology measurements of a sample. A modeled correction may be generated based on the metrology measurements and the value of the regularization parameter using the regression. The regression may reduce a residual between the modeled correction and the metrology measurements. The model terms may include a sub-set of possible model terms up to a maximum order. Selecting the model terms from the possible model terms may prevent overfitting the modeled correction. The regularization parameter may control the number of the model terms which are selected.

### TECHNICAL FIELD

The present disclosure generally relates to semiconductor metrology, and, more particularly, to process control using metrology.

### BACKGROUND

Current trends in the manufacturing of semiconductor devices by processing of the semiconductor wafers mean that overlay and critical dimension budgets shrink with shrinking ground rules and the semiconductor manufacturing processes are becoming more aggressive. Examples of such aggressive semiconductor manufacturing processes include, but are not limited to, multiple patterning, and high aspect ratio etching or deposition of exotic materials on a surface of the semiconductor wafer. The non-uniformity of some of the semiconductor manufacturing processes over the semiconductor wafer surface and a plurality of semiconductor manufacturing process steps may result in non-uniform stress being applied to the semiconductor wafer.

Overlay error and critical dimension error may occur when processing the semiconductor wafer. The overlay error may occur when the semiconductor wafer deforms from one process step to a subsequent process step, e.g. from one lower layer to a subsequent layer on top of the lower layer, patterns in the upper layer become misaligned with respect to patterns in the lower layer. The critical dimension error may occur due to non-uniformities introduced by etch processes, spin coating, baking, and the like. For the error free functioning of the semiconductor device, the relative position of the patterns on the different layers to each other is relevant. The reason for this misalignment can be multi-fold and may depend on the different process steps.

Difficulties may arise in evaluating and controlling the semiconductor manufacturing process to identify and/or correct for such issues in the semiconductor manufacturing process. Therefore, it would be advantageous to provide a device, system, and method that cures the shortcomings described above.

### SUMMARY

A metrology system is described, in accordance with one or more embodiments of the present disclosure. The metrology system may include: a metrology sub-system; and a controller communicatively coupled to the metrology sub-system, wherein the controller includes one or more processors configured to execute program instructions stored in memory, the program instructions configured to cause the one or more processors to: receive a plurality of metrology measurements of a sample; select a value of a regularization parameter by cross-validating the regularization parameter across a range of possible values using the plurality of metrology measurements; and generate a modeled correction based on the plurality of metrology measurements and the value of the regularization parameter using a regression that reduces a residual between the modeled correction and the plurality of metrology measurements, wherein the modeled correction is defined by a plurality of model terms, wherein the plurality of model terms includes a sub-set of possible model terms up to a maximum order, wherein the regularization parameter controls a number of the plurality of model terms which are selected as the sub-set.

A metrology system is described, in accordance with one or more embodiments of the present disclosure. The metrology system may include: a controller including one or more processors configured to execute program instructions stored in memory, the program instructions configured to cause the one or more processors to: receive a plurality of metrology measurements of a sample; select a value of a regularization parameter by cross-validating the regularization parameter across a range of possible values using the plurality of metrology measurements; and generate a modeled correction based on the plurality of metrology measurements and the value of the regularization parameter using a regression that reduces a residual between the modeled correction and the plurality of metrology measurements, wherein the modeled correction is defined by a plurality of model terms, wherein the plurality of model terms includes a sub-set of possible model terms up to a maximum order, wherein the regularization parameter controls a number of the plurality of model terms which are selected as the sub-set.

A method is described, in accordance with one or more embodiments of the present disclosure. The method may include: receiving a plurality of metrology measurements of a sample; selecting a value of a regularization parameter by cross-validating the regularization parameter across a range of possible values using the plurality of metrology measurements; and generating a modeled correction based on the plurality of metrology measurements and the value of the regularization parameter using a regression that reduces a residual between the modeled correction and the plurality of metrology measurements, wherein the modeled correction is defined by a plurality of model terms, wherein the plurality of model terms includes a sub-set of possible model terms up to a maximum order, wherein the regularization parameter controls a number of the plurality of model terms which are selected as the sub-set.

### BRIEF DESCRIPTION OF THE DRAWINGS

The numerous advantages of the disclosure may be better understood by those skilled in the art by reference to the accompanying figures in which:

FIG. 1A depicts a simplified block diagram of a metrology system, in accordance with one or more embodiments of the present disclosure.

FIG. 1B depicts a simplified block diagram of a metrology sub-system of the metrology system, in accordance with one or more embodiments of the present disclosure.

FIG. 2 depicts a flow diagram of a method, in accordance with one or more embodiments of the present disclosure.

FIG. 3A depicts an example of measurement values of samples, in accordance with one or more embodiments of the present disclosure.

FIG. 3B depicts an example chart including model terms and a root mean square error of the model terms as a function of a regularization parameter, in accordance with one or more embodiments of the present disclosure.

FIG. 3C depicts an example Zernike polynomial of a thirteen order with model terms selected using the regularization parameter to reduce the root mean square error, in accordance with one or more embodiments of the present disclosure.

FIG. 3D depicts a modeled correction determined from the model terms, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

Modeling of fingerprints is a procedure for error corrections in the lithography step of semiconductor manufacturing. The fingerprints may include wafer fingerprints, field fingerprints, and/or die/chip fingerprints. The field may refer to the field defined by an exposure tool in a step and scan methodology. The resulting model of the fingerprints may be used to create corrections that are applied to future exposures. A polynomial model type (cartesian, Zernike, Legendre, . . . ) and a selection of model terms is chosen. This model is then fitted to measurement data. Choosing too many model terms may risk overfitting such that the model generalizes badly and over-corrects future exposures. Choosing too few model terms cannot capture a fingerprint's details and under-corrects future exposures.

Embodiments of the present disclosure are directed to automated model term selection for monitoring and optimized process control. The automated model term selection may use lasso regression for selecting model terms and a cross-validation scheme to optimize a regularization parameter of the lasso regression. A value of the regularization parameter may be selected by cross-validating the regularization parameter across a range of possible values using metrology measurements of a sample. A modeled correction may be generated based on the metrology measurements and the value of the regularization parameter using the regression. The regression may reduce a residual between the modeled correction and the metrology measurements. The model terms may include a sub-set of possible model terms up to a maximum order. Selecting the model terms from the possible model terms may prevent overfitting of the modeled correction. The regularization parameter may control the number of the model terms which are selected.

U.S. Patent Publication Number US20240093985A1, titled “System and method for acquiring alignment measurements of structures of a bonded sample”; U.S. Pat. No. 10,234,401B2, titled “Method of manufacturing semiconductor devices by using sampling plans”; U.S. Pat. No. 10,310,490B2, titled “Method and apparatus of evaluating a semiconductor manufacturing process”; U.S. Pat. No. 10,545,412B2, titled “Statistical overlay error prediction for feed forward and feedback correction of overlay errors, root cause analysis and process control”; U.S. Pat. No. 10,867,877B2, titled “Targeted recall of semiconductor devices based on manufacturing data”; U.S. Pat. No. 11,092,901B2, titled “Wafer exposure method using wafer models and wafer fabrication assembly”; U.S. Pat. No. 11,181,830B2, titled “Lithographic apparatus and method of controlling a lithographic apparatus”; U.S. Pat. No. 11,221,300B2, titled “Determining metrology-like information for a specimen using an inspection tool”; U.S. Pat. No. 11,293,970B2, titled “Advanced in-line part average testing”; U.S. Pat. No. 11,429,091B2, titled “Method of manufacturing a semiconductor device and process control system for a semiconductor manufacturing assembly”; U.S. Pat. No. 9,052,709B2, titled “Method and system for providing process tool correctables”; U.S. Pat. No. 11,340,060B2, titled “Automatic recipe optimization for overlay metrology system”; are each incorporated herein by reference in the entirety.

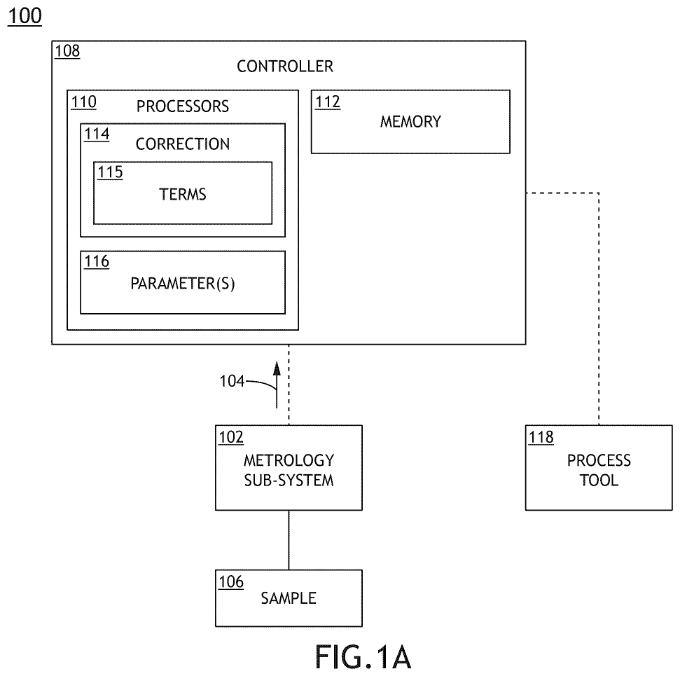

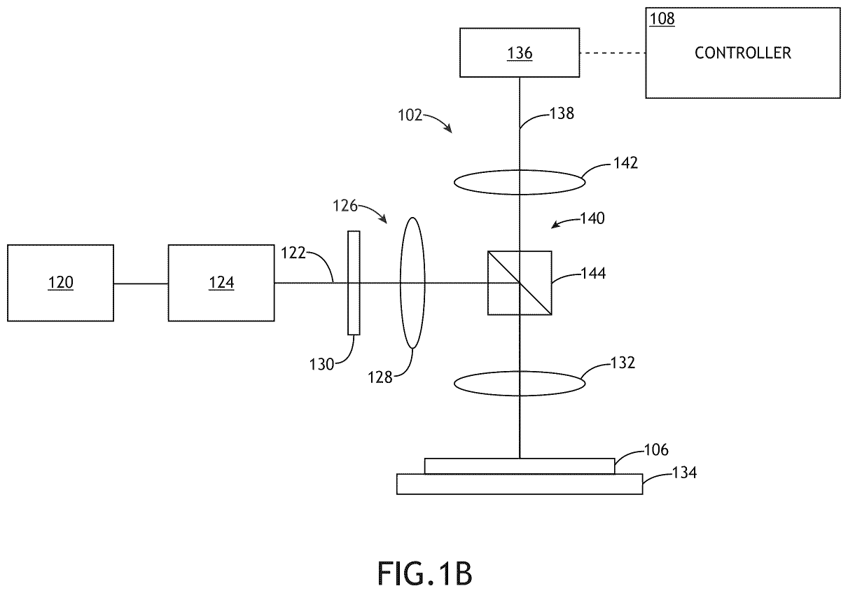

FIG. 1A depicts a metrology system 100, in accordance with one or more embodiments of the present disclosure. The metrology system 100 may include a metrology sub-system 102. The metrology system 100 may generally include any number or type of metrology sub-systems 102 and each metrology sub-system 102 may generally include any number or type of sub-systems (e.g., metrology and/or inspection sub-systems). The metrology sub-system 102 may include one or more metrology tools.

The metrology sub-system 102 may include any combination of metrology sub-systems such as, but not limited to, optical metrology systems (e.g., light-based metrology systems), scatterometry metrology sub-systems, particle-based metrology systems, probe-based systems, an electron beam metrology sub-system (e.g., scanning electron microscope metrology sub-system or the like), or the like.

The metrology sub-system 102 may characterize and/or screen a sample 106. The metrology sub-system 102 may characterize and/or screen the sample 106 at various steps of the manufacturing process in which the sample 106 is manufactured. The metrology sub-system 102 may include any type of metrology tool suitable for any type of metrology and/or inspection measurements at any point of the manufacturing process.

The sample 106 may include any number and type of samples. For example, the sample 106 may be a wafer (e.g., a semiconductor wafer), a pre-bonded substrate (e.g., pre-bonded die), a coupled sample formed from two substrates (e.g., die to wafer, wafer to wafer, die to die, and the like), a pre-diced wafer, or any other type or combination of samples. For instance, the sample 106 may include a coupled sample formed from two substrates coupled together at an interface. Note that, while a sample 106 may be described in terms of being or including a “die”, such a term is nonlimiting and any descriptions and methodologies herein may be applicable to a “chiplet”, a “chip”, multiple dies/chiplets collectively coupled in-plane together, a full wafer, a partially diced wafer, a plurality of multiple stacked bonded dies/chiplets/wafers configured to be bonded to another wafer, and the like.

The sample 106 may be formed from any material or combination of materials including, but not limited to, a wafer substrate, a semiconductor, a metal, a polymer, a glass, a crystalline material, semiconductor-on-insulator (SOI), or the like. A wafer substrate may be a thin disc that includes a substrate material. The substrate material may include a semiconducting material. For example, the wafer substrate may be a semiconductor wafer, a glass substrate including one or more semiconducting layers, or an SOI (silicon-on-insulator) wafer, by way of example.

The sample 106 may include structures. The structures may be formed on or in a wafer substrate of the sample 106. The structures may also be referred to as features, deposited films, fabricated features, and the like. The structures may be any structure to which a measurement may be taken. For example, a structure generally could be, but is not limited to, an electrically functional structure such as a portion of a logic gate or transistor, a nonfunctional structure such as a dedicated overlay target, an edge of a die/wafer, or any other measurable structure. The structures may include trenches extending from a main surface at a front side of the wafer substrate into the wafer substrate. The trenches may be filled with a material different from a surrounding substrate material. The structures may project from a main surface at a front side of the wafer substrate. The structures which project from the main surface may include, e.g., pillars, stripe-shaped ribs, line patterns, photoresist structures, and the like. The structures may be semiconductor layers, semiconductor elements, semiconductor devices, or the like. The structures may form memory devices, microprocessors, logic circuits, analog circuits, power semiconductor devices, and the like. The structures may be formed on a main surface of a wafer substrate. The structures may include an activated or deactivated photoactive component. The structures may be obtained by developing an exposed photoresist layer. The structures may include a plurality of laterally separated resist features.

The structures of the sample 106 may be manufactured during a semiconductor manufacturing process. There may be many process steps in the semiconductor manufacturing process that may cause variations of overlay (OVL) between layers or variations of critical dimensions (CD) of the structures. The variations may change over a chip/die per field, over a field, over the sample 106, and/or over a lot including multiple of the samples 106.

The metrology system 100 may generate metrology measurements 104 of the sample 106. For example, the metrology sub-system 102 may generate the metrology measurements 104. The metrology measurements 104 may be metrology measurements of the structures of the sample 106.

The metrology measurements 104 may be generated after processing of the structures. For example, the metrology measurements 104 may be generated after patterning of a lithographic layer, deposition, etching, exposure, development, and the like. The structures may be formed via processes such as heating, layer formation, patterning, etching, grinding, or implanting.

The metrology measurements 104 may be from different locations of the sample 106. The metrology system 100 may generate the metrology measurements 104 at metrology sites. The metrology sites may be distributed across the sample 106. The metrology sites may have circular, elliptical or rectangular shape. The size of the metrology sites depends on the measurement method. For example, a diameter or edge length of the metrology sites may be about 100 μm for scatterometric methods and about 1 μm for measurements using electron microscopy. The metrology sites at which the metrology measurements are generated may be independent of the results of an inspection process performed on the sample 106. Since locations on the specimen at which metrology is performed may be selected independently of inspection results, the metrology measurements may be generated before, simultaneously with, and/or after an inspection process has been performed on the sample 106.

The metrology sites may be defined in a sampling plan. The sampling plan may include wafer identification information for identifying the sample 106 and further includes position information identifying the metrology sites selected for measurement. A number and position of the sampling points may be defined in the sampling plan. The sampling plan may be initialized according to previously obtained knowledge. The metrology sites may be within exposure fields, may be outside the exposure fields, e.g., in a wafer edge area, within chip areas and/or outside the chip areas, e.g., in the kerf area of the sample 106. The sampling plan may be static or may be dynamic. In a static sampling plan, the position of one or more sampling points and/or the number of sampling points may fixed. In a dynamic sampling plan, the position of one or more sampling points may change and/or the number of sampling points may change with time.

The metrology measurements 104 may include any suitable metrology measurement of the sample 106. For example, the metrology measurements 104 may include overlay, critical dimensions (CDs), wafer shape, and the like.

The overlay may also be referred to as an overlay measurement. The overlay may be generated between two or more of the structures of the sample 106. The overlay may include the position of the overlay marks, the measurement orientation of the overlay marks, dispositioning values between two layers, quality parameters, and the like. The overlay may be a measurable error in alignment of a center of symmetry of structures. The overlay may be error between an intended pattern or structure placement and the actual pattern or structure placement. For example, the overlay may mean errors such as a lateral shift, rotation, magnification, and/or combination of such errors of a placement of an overlay target or a pattern of devices. The overlay may be position-dependent and may include at least one of a linear offset between the structures, a magnification or size reduction of the structures, and a rotation of the structures. The overlay may include direct overlay and/or registration overlay. Direct overlay may be an overlay between a structure in a layer immediately above, and adjacent or overlapping to a structure in a lower layer. Registration overlay may be an overlay of structures in different layers that are not overlapping and are spaced apart a distance. For example, an overlay target spaced apart from a functional structure may be used to acquire a registration overlay measurement.

The critical dimensions may also be referred to as critical dimension measurements. The critical dimensions may concern any feature characteristic of a critical resist feature. The critical dimensions may quantitatively describe a physical property of one of the structures and/or a positional relationship between multiple of the structures. The critical dimensions may include the position, geometric dimensions, and/or derived data of the structures of the sample 106. The geometric dimensions may include height, width, and/or length of the structures on a surface of the sample 106 within the measurement area. The critical dimensions may include spaces of critical resist features, areas of critical resist features, and the like. The critical dimensions may include a diameter of a circular resist feature, lengths of short axes and long axes of non-circular resist features, a line width of a stripe-shaped resist feature, a width of spaces between resist features, sidewall angles of resist features, areas of resist features and other properties such as line edge roughness of resist features, and the like. For example, the critical dimensions may include a width of a line or a vertical extension of a step or a trench, a sidewall angle of a protrusion extending from a surface of the sample 106, or a sidewall angle of a trench extending into a surface of the sample 106. By way of another example, the critical dimensions may include a thickness and/or composition of a topmost layer covering the sample 106 or about other physical properties or characteristics such as line edge roughness, line width roughness, overlay data, wafer shape, wafer deformation, defect density as well as about results of defect and electrical measurements.

The wafer shape may refer to other physical properties of the sample 106. For example, the wafer shape may refer to height maps, wafer bowing, wafer warping, and the like. The metrology measurements 104 may also characterize aspects of bare wafers and/or un-patterned films such as, but not limited to, wafer thickness, wafer flatness, film thickness, film flatness, refractive index, or stress.

The metrology system 100 may include a controller 108. The controller 108 may include processors 110 configured to execute program instructions maintained on memory 112 (e.g., a memory medium). Further, the controller 108 may be communicatively coupled with any of the components of the metrology system 100 including, but not limited to, the metrology sub-system 102 and any other sub-systems. In this regard, the processors 110 of the controller 108 may execute any of the various process steps described throughout the present disclosure. The controller 108 may receive the metrology measurements 104 from the metrology sub-system 102. The controller 108 may use the metrology measurements 104 for one or more purposes.

The controller 108 may be configured to perform automated process control (APC). The metrology measurements 104 may determine a variation by comparing the actual values of the metrology measurements 104 to target values of the metrology measurements 104. The comparison may be used in a control loop. The controller 108 may include control loops to control the variations of the metrology measurements 104 (e.g., overlay and/or critical dimensions). The metrology measurements 104 may be used in a feed forward and/or feed backward recipe. The metrology measurements 104 may be used to correct for the metrology measurements 104 of the sample 106 in a feed backward recipe and/or may be used to correct the metrology measurements 104 of the samples 106 in a feed forward recipe. The metrology measurements 104 may be used for material excursion control or for any other use of a fabrication process. The variation may be determined over a field within the sample 106, over the sample 106, and/or over a lot including multiple of the samples 106.

The controller 108 may generate a modeled correction 114. The modeled correction 114 may also be referred to as correctables. The controller 108 may generate the modeled correction 114 based on the metrology measurements 104 and a value of a regularization parameter 116.

The controller 108 may generate the modeled correction 114 using a wafer exposure model. The wafer exposure model may interpolate the modeled correction 114 based on the metrology measurements 104. The controller 108 may update the coefficients of the wafer exposure model based on the metrology measurements 104.

The modeled correction 114 may be a systematic signature which is extracted from the metrology measurements 104. The modeled correction 114 may be any class of linear model or polynomial model. For example, the modeled correction 114 may be extracted from the metrology measurements 104 using model terms 115. The modeled correction 114 may be defined by a sum of the model terms 115 and/or principal components of the signature.

The modeled correction 114 may include model terms 115 of a certain type up to a maximum order. For example, the model terms 115 may include all or a sub-set of possible model terms up to the maximum order. The maximum order of the model terms 115 may be between three and ten. It is further contemplated that the order of the model terms 115 may be up to thirteen, fourteen, fifteen, or more, using one or more of the embodiments of the present disclosure to prevent overfitting.

The modeled correction 114 may be defined by the model terms 115 with polar coordinates and/or cartesian coordinates. The model terms 115 may include polar coordinates and/or cartesian coordinates for inter-field correction. Inter-field correction may reduce substrate-level deviations. The substrate-level deviations may include effects based on deposition effects, wafer bowing, and others. The model terms 115 may include cartesian coordinates for intra-field correction and/or for intra-die corrections. The intra-field corrections may reduce reticle effects and/or design-specific effects. The intra-die corrections may reduce topography and/or sample density induced effects. The modeled correction 114 may include any suitable polynomial, such as, a Zernike polynomial, Legendre polynomial, or the like.

Zernike polynomials may be defined in the polar coordinate system and/or the cartesian coordinate system. Due to the shape of the sample 106 and to the nature of the processes, many process deviations result in errors that can be comparatively well described with Zernike polynomials. A range of corrections may be determined for a given nonlinear function. The range of corrections may be higher order terms of a fitted model.

Legendre polynomials may be defined in the cartesian coordinate system. The Legendre polynomials may be a point symmetric approximation that approximates the distribution of the metrology measurements 104 in a closed form.

The modeled correction 114 may be selected to approximate the metrology measurements 104 while minimizing an error function. The coefficients of the modeled correction 114 may be obtained using a fitting algorithm. The fitting algorithm may search for coefficients that minimize deviations between the modeled correction 114 and the metrology measurements 104. The fitting algorithm may include a least squares method (LSM).

A residual may be a measure for the remaining deviation between the modeled correction 114 and the metrology measurements 104. In particular, the total magnitude of the residuals may give an impression of the quality of the modeled correction 114. With increasing number of the model terms 115 in the modeled correction 114, the overall residuals get lower. But with increasing number of the model terms 115, the modeled correction 114 may follow process-insignificant noise. Therefore, selecting the number of the model terms 115 within a threshold may be desirable to provide residuals and susceptivity to noise within tolerance.

The modeled correction 114 may be generated using a regression that reduces the residuals between the modeled correction 114 and the metrology measurements 104. For example, the regression may reduce a root mean squared error (RMSE) between the metrology measurements 104 and the modeled correction 114.

The regression may include lasso regression. The controller 108 may use the lasso regression to determine the model terms 115 when generating the modeled correction 114. The controller 108 may determine the model terms 115 used to fit the modeled correction 114 to the metrology measurements 104. The controller 108 may determine the model terms 115 using lasso regression. The lasso regression may also be referred to as a least absolute shrinkage and selection operator regression or an L1 regression. The lasso regression may determine the model terms 115 from a sub-set of possible model terms up to the maximum order.

The controller 108 may or may not enforce using one or more specific model terms of the possible model terms during the regression thereby ensuring the one or more specific model terms are included in the modeled correction 114. For example, the controller 108 may enforce using specific model terms of the possible model terms during the regression by fitting an initial of the modeled correction 114 with the specific model terms to the metrology measurements 104 followed by model term selection on the residuals of the initial of the modeled correction 114. The specific model terms may then be included as one or more of the model terms 115 defining the modeled correction 114.

The regularization parameter 116 may be a hyperparameter of the modeled correction 114. The regularization parameter 116 may be referred to as an L1 parameter, a λ parameter, or a penalty parameter. The regularization parameter 116 may cause the controller 108 to remove one or more of the model terms 115 from the modeled correction 114. The regularization parameter 116 may control the number of the model terms 115 which are selected as the sub-set of possible model terms. For example, the regularization parameter 116 may be added as a penalty term to the residual. Larger values of the regularization parameter 116 may result in selecting a smaller number of the model terms 115.

The controller 108 may select a value of the regularization parameter 116 from a range of possible values. The value of the regularization parameter 116 may strongly affect the lasso regression. The range of possible values may be maintained in memory 112. The controller 108 may select the value of the regularization parameter 116 by measuring the performance of all possible of the regularization parameters 116 in a pre-determined valid range.

The controller 108 may select the value of the regularization parameter 116 by cross-validating the regularization parameter 116 across a range of possible values using the metrology measurements 104. The cross-validation may include leave-one-out cross-validation, K-fold cross-validation, hold-out cross-validation, or the like. The cross-validation may optimize the value of the regularization parameter 116 used in the regression.

The cross-validation may evaluate the performance of each of the range of possible values of the regularization parameter 116 based on the modeled correction 114 determined for the range of possible values of the regularization parameter 116. For example, the controller 108 may use the regression to determine possible model terms for each of the range of possible values and evaluate the possible model terms against the metrology measurements 104. The value of the regularization parameter 116 with a best performance may be selected. The best performance may be determined from an application specific and meaningful optimization criterion. Evaluating the possible model terms against the metrology measurements 104 may include determining a root mean square error between the possible model terms and the metrology measurements. The controller 108 may select the value of the regularization parameter 116 which minimizes the root mean square error between the possible model terms and the metrology measurements.

The cross-validation may include one or more steps. For example, the cross-validation may include cross-validating across multiple of the samples 106 and/or cross-validating across multiple sampling marks and/or data points. The controller 108 may select the value of the regularization parameter 116 which is cross-validated to generate a minimum root mean square error across the samples 106 and/or across multiple sampling marks and/or data points.

The sample 106 may be one of multiple samples. The metrology measurements 104 may be from the multiple samples. The controller 108 may cross-validate the regularization parameter 116 across multiple of the samples 106. The controller 108 may cross-validate the regularization parameter 116 across multiple of the samples 106 to test the robustness of the model terms 115. The robustness may be defined as a root mean square error (RMSE) between the metrology measurements 104 across multiple of the samples 106 and the model terms 115 determined using the regularization parameter 116.

The controller 108 may weigh the metrology measurements 104 using a weighted average when cross-validating the value of the regularization parameter 116. The weighted average may be across multiple of the samples 106. For example, the controller 108 may give more weight to the metrology measurements 104 which are from newer of the samples 106. Thus, the controller 108 may weigh the metrology measurements 104 by time of measurement with higher weights for relatively recent times of measurement.

The controller 108 may also cross-validate the value of the regularization parameter 116 across the sample 106. The controller 108 may cross-validate the value of the regularization parameter 116 across sampling marks and/or data points of the sample 106. The sampling marks and/or data points may be metrology measurements 104 associated with one of the samples 106. The sampling marks and/or data points may include fields, dies, and/or structures of the sample 106. Cross-validating the value of the regularization parameter 116 across sampling marks and/or data points may test if the model terms 115 accurately describe a current fingerprint of the sample 106.

Using cross-validation, the controller 108 may determine how well the value of the regularization parameter 116 works on a sub-set of the metrology measurements 104. The controller 108 may determine the value of the regularization parameter 116 upon determining which of the range of possible values of the regularization parameter 116 works best on a sub-set of the metrology measurements 104.

The controller 108 may apply the value of the regularization parameter 116 to the metrology measurements 104 to generate the modeled correction 114. The controller 108 may determine the model terms 115 of the modeled correction 114 from the metrology measurements by performing the lasso regression with the value of the regularization parameter 116. The model terms 115 are fit to the metrology measurements 104 to establish the modeled correction 114. A final regression and model term selection may be performed using the value of the regularization parameter 116 determined from cross-validation to determine the modeled correction 114 and the model terms 115.

The controller 108 may select the model terms 115 from a sub-set of possible model terms of a given order. The cross-validation may cause the controller 108 to select the model terms 115 during the lasso regression to avoid overfitting the modeled correction 114 to the metrology measurements 104. Selecting the model terms 115 from the sub-set of the possible model terms of the given order may be beneficial to prevent overfitting the modeled correction 114 to the metrology measurements 104. Using all model terms of the given-order may show significant overfitting, especially at the edges of the sample 106. This highlights the importance of selecting the model terms 115 from the sub-set that describe the fingerprint. Thus, a wider range of fingerprints can be captured with a given number of the metrology measurements 104 without risking overfitting, since individual high-order of the model terms 115 may be included in the modeled correction 114.

Selecting the regularization parameter and performing the lasso regression may automate generation of the modeled correction 114. Automating the generation of the modeled correction 114 by the controller 108 may be beneficial to reduce a setup effort of the metrology system 100. Automating the generation of the modeled correction 114 may also enable unsupervised adaptive modeling in a monitoring setup since new fingerprints or the presence of new versions of the model terms 115 can be discovered automatically.

The controller 108 may adapt the modeled correction 114 to new sets of the metrology measurements 104 using the regularization parameter 116. For example, the modeled correction 114 and/or the model terms 115 may be adjusted to new fingerprints in the metrology measurements 104. Combining time windows and time-based weighting of measurements with the adaptive modeling may increase a level of automated process correction. Thus, the controller 108 may be adaptable new fingerprints in a run-to-run setup.

The controller 108 may generate the modeled correction 114 from any dataset of the metrology measurements 104 taken from the sample 106 or multiple of the samples 106. For example, the metrology measurements 104 may be from one, two, or more of the samples 106. When splitting a larger dataset, the modeled correction 114 may be used to compare fingerprints between the metrology measurements 104 generated with different contexts. The different contexts may include exposure tools used to form the structures, scan directions, metrology tools to generate the metrology measurements 104, and the like.

The controller 108 may generate the modeled correction 114 from a sliding window of the metrology measurements 104 over time to find changes in the model terms 115 and/or the value of the regularization parameter 116. The model terms 115 and/or the value of the regularization parameter 116 may change with the change in the measured fingerprints over time. The model terms 115 and/or the value of the regularization parameter 116 may be very stable over time or may fluctuate with process variations. The changes in the model terms 115 and/or the value of the regularization parameter 116 may ensure that the modeled correction 114 for the process tool 118 are optimal to describe and correct the currently measured fingerprint to accommodate the process variations.

The modeled correction 114 may include one or more process correction parameters. The process correction parameters may be defined as a function of the position coordinates. The process correction parameters may be used to compensate for process errors in the sample 106. The modeled correction 114 may include alignment, dose corrections, focus corrections, overlay corrections, and the like. The dose corrections and/or the focus corrections may be selected to compensate for intra-field deviations. For example, uncorrected illumination non-uniformities, mask aberrations, and/or projection lens aberrations may result in different imaging properties within the exposure field that may be compensated by changing the predetermined focus and/or dose values as a function of the x coordinates and the y coordinates within the exposure field.

The modeled correction 114 may be used to monitor or adjust a process tool 118. For example, the process tool 118 may be a lithography tool, a deposition tool, an etching tool, scanner tool, or the like. The modeled correction 114 may be a correction which the process tool 118 may use to perform a given process on the sample 106. The controller 108 may control the process tool 118 based on the modeled correction 114 with at least one of a feedback control or a feedforward control. For example, the modeled correction 114 may correct the process used to form the structures on the sample 106. The modeled correction 114 may include data used to correct the alignment of the process tool 118 to improve the control of subsequent lithographic patterning with respect to overlay performance. The modeled correction 114 may allow the process to proceed within predefined limits by providing feedback control and/or feedforward control to improve the alignment of the process tool 118. The modeled correction 114 may be displayed, transmitted to a higher-order process monitoring and/or administration system and/or may be used for controlling the exposure process across the complete main surface of a next sample or for a rework of the current sample.

The modeled corrections 114 may be applied to a combined linear model for global optimization. When multiple of the modeled corrections 114 are generated, such as for lots, wafers, and exposure fields, the approach may be applied to each of the modeled corrections 114 individually to capture fingerprints on the different levels. The modeled correction 114 may include intra-die corrections and/or inter-die corrections. The intra-die corrections may include corrections within the die structures of the sample 106. The inter-die corrections may include corrections between multiple of the die structures of the sample 106.

Multiple of the samples 106 of a batch (e.g., a wafer lot) may be subjected to the same processes for forming the same structures. The modeled correction 114 may adjust the process used to form the structures on the samples 106 of the batch via the feedback control. Metrology processes may be used at various steps during a semiconductor manufacturing process to monitor and control the process.

FIG. 1B depicts an example of the metrology sub-system 102, in accordance with one or more embodiments of the present disclosure. The metrology sub-system 102 may include an illumination source 120 configured to generate an illumination beam 122. The illumination beam 122 may include one or more selected wavelengths of light including, but not limited to, ultraviolet (UV) radiation, visible radiation, or infrared (IR) radiation.

The illumination source 120 may include any type of illumination source suitable for providing an illumination beam 122. The illumination source 120 may be a laser source. For example, the illumination source 120 may include, but is not limited to, one or more narrowband laser sources, a broadband laser source, a supercontinuum laser source, a white light laser source, or the like. In this regard, the illumination source 120 may provide an illumination beam 122 having high coherence (e.g., high spatial coherence and/or temporal coherence). The illumination source 120 may be a laser-sustained plasma (LSP) source. For example, the illumination source 120 may include, but is not limited to, a LSP lamp, a LSP bulb, or a LSP chamber suitable for containing one or more elements that, when excited by a laser source into a plasma state, may emit broadband illumination. The illumination source 120 may include a lamp source. For example, the illumination source 120 may include, but is not limited to, an arc lamp, a discharge lamp, an electrode-less lamp, or the like. In this regard, the illumination source 120 may provide an illumination beam 122 having low coherence (e.g., low spatial coherence and/or temporal coherence). The illumination source 120 may include a synchrotron source.

The metrology system 100 may include a wavelength selection device 124 to control the spectrum of the illumination beam 122 for illumination of the sample 106. For example, the wavelength selection device 124 may include a tunable filter suitable for providing an illumination beam 122 with a selected spectrum (e.g., center wavelength, bandwidth, spectral profile, or the like). By way of another example, the wavelength selection device 124 may adjust one or more control settings of the illumination source 120 to directly control the spectrum of the illumination beam 122. Further, the controller 108 may be communicatively coupled to the illumination source 120 and/or the wavelength selection device 124 to adjust one or more aspects of the spectrum of the illumination beam 122.

The metrology sub-system 102 may direct the illumination beam 122 to the sample 106 via an illumination pathway 126. The illumination pathway 126 may include one or more optical components suitable for modifying and/or conditioning the illumination beam 122 as well as directing the illumination beam 122 to the sample 106. For example, the illumination pathway 126 may include, but is not required to include, one or more lenses 128 (e.g., to collimate the illumination beam 122, to relay pupil and/or field planes, or the like), one or more polarizers 130 to adjust the polarization of the illumination beam 122, one or more filters, one or more beam splitters, one or more diffusers, one or more homogenizers, one or more apodizers, one or more beam shapers, or one or more mirrors (e.g., static mirrors, translatable mirrors, scanning mirrors, or the like). The metrology sub-system 102 may include an objective lens 132 to focus the illumination beam 122 onto the sample 106 (e.g., an overlay target with overlay target elements located on two or more layers of the sample 106). In another embodiment, the sample 106 is disposed on a sample stage 134 suitable for securing the sample 106 and further configured to position the sample 106 with respect to the illumination beam 122.

The metrology sub-system 102 may include a detector 136 configured to capture radiation (e.g., sample radiation 138) emanating from the sample 106 (e.g., an overlay target on the sample 106) through a collection pathway 140 and generate one or more overlay signals indicative of overlay of two or more layers of the sample 106. The collection pathway 140 may include multiple optical elements to direct and/or modify illumination collected by the objective lens 132 including, but not limited to one or more lenses 142, one or more filters, one or more polarizers, one or more beam blocks, or one or more beamsplitters. For example, the detector 136 may receive an image of the sample 106 provided by elements in the collection pathway 140 (e.g., the objective lens 132, the one or more lenses 142, or the like). By way of another example, the detector 136 may receive radiation reflected or scattered (e.g., via specular reflection, diffuse reflection, and the like) from the sample 106. By way of another example, the detector 136 may receive radiation generated by the sample (e.g., luminescence associated with absorption of the illumination beam 122, and the like). By way of another example, the detector 136 may receive one or more diffracted orders of radiation from the sample 106 (e.g., 0-order diffraction, ±1 order diffraction, ±2 order diffraction, and the like).

The illumination pathway 126 and the collection pathway 140 of the metrology sub-system 102 may be oriented in a wide range of configurations suitable for illuminating the sample 106 with the illumination beam 122 and collecting radiation emanating from the sample 106 in response to the illumination beam 122. For example, the metrology sub-system 102 may include a beamsplitter 144 oriented such that the objective lens 132 may simultaneously direct the illumination beam 122 to the sample 106 and collect radiation emanating from the sample 106. By way of another example, the illumination pathway 126 and the collection pathway 140 may contain non-overlapping optical paths.

The detector 136 may generate the metrology measurements 104. For example, the detector 136 may generate the metrology measurements 104 based on the sample radiation 138 captured by the detector 136. The detector 136 may provide the metrology measurements 104 to the controller 108.

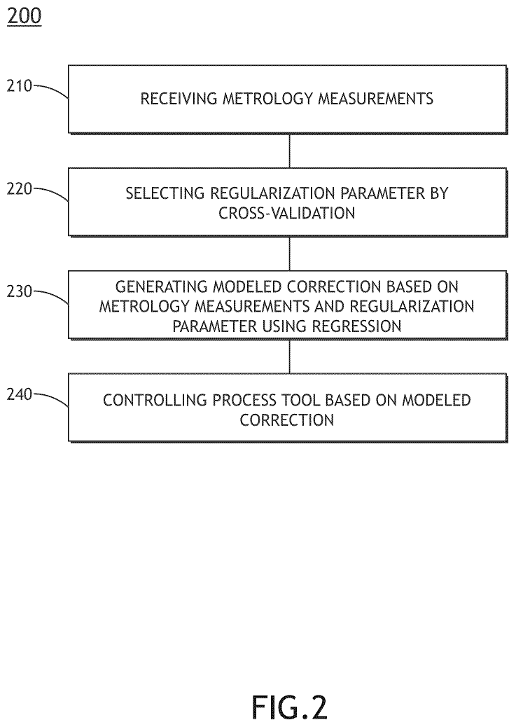

FIG. 2 depicts a flow diagram of a method 200, in accordance with one or more embodiments of the present disclosure. The embodiments and the enabling technologies described previously herein in the context of the metrology system 100 should be interpreted to extend to the method 200. It is further noted, however, that the method 200 is not limited to the architecture of the metrology system 100.

In a step 210, metrology measurements may be received. The controller 108 may receive the metrology measurements 104. The controller 108 may receive the metrology measurements 104 from the metrology sub-system 102. For example, the metrology measurements 104 may be generated by the metrology sub-system 102 and provided to the controller 108. The metrology measurements 104 may be generated at one or more positions on the sample 106.

In a step 220, a value of a regularization parameter may be selected. For example, the controller 108 may select the value of the regularization parameter 116. The value of the regularization parameter 116 may be selected by cross-validating the regularization parameter 116 across a range of possible values using the metrology measurements 104.

In a step 230, a modeled correction may be generated based on the metrology measurements and the value of the regularization parameter. For example, the controller 108 may generate the modeled correction 114 based on the metrology measurements 104 and the value of the regularization parameter 116. The modeled correction 114 may be generated using the regression that reduces a residual between the modeled correction 114 and the metrology measurements 104. The modeled correction may be defined by the model terms 115. The model terms 115 may include a sub-set of possible model terms up to a maximum order. The regularization parameter 116 may control the number of the model terms 115 which are selected.

In a step 240, a process tool may be controlled based on the modeled correction with at least one of a feedback control or a feedforward control. For example, the controller 108 may control the process tool 118 based on the modeled correction 114 with at least one of a feedback control or a feedforward control. The structures of the sample 106 may be corrected using the modeled correction 114. For example, the controller 108 may cause the structures of the sample 106 to be corrected using the modeled correction 114 via feedforward control. The structures of subsequent of the samples in a lot may be corrected using the modeled correction 114. For example, the controller 108 may cause the structures of subsequent of the samples in a lot to be corrected using the modeled correction 114 via feedback control.

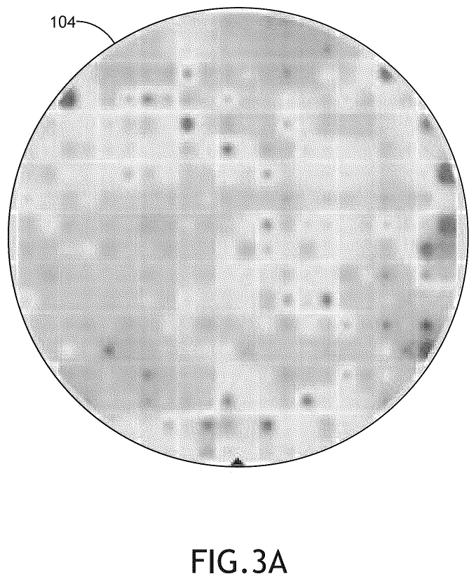

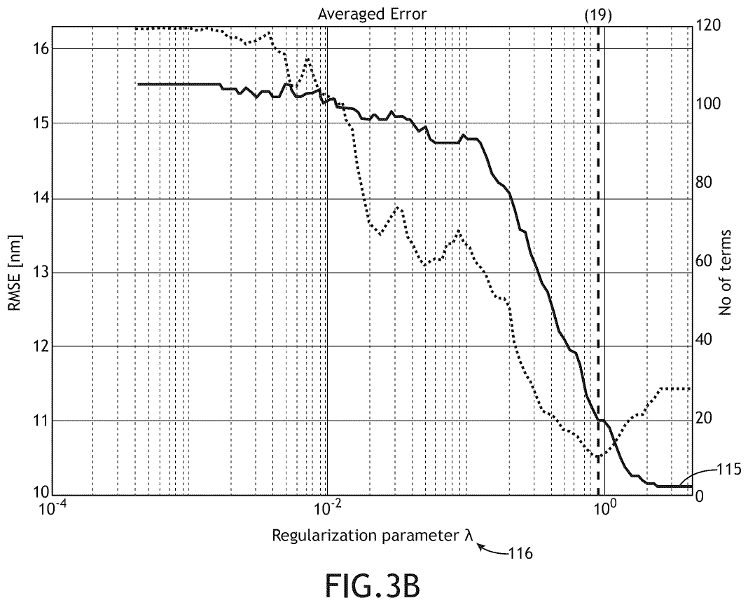

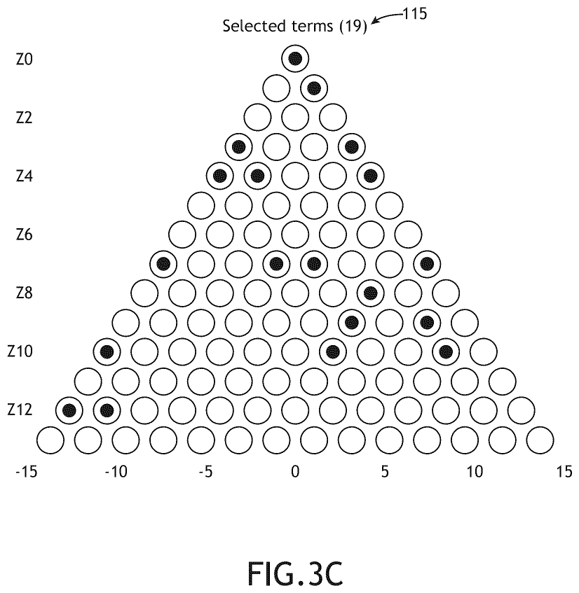

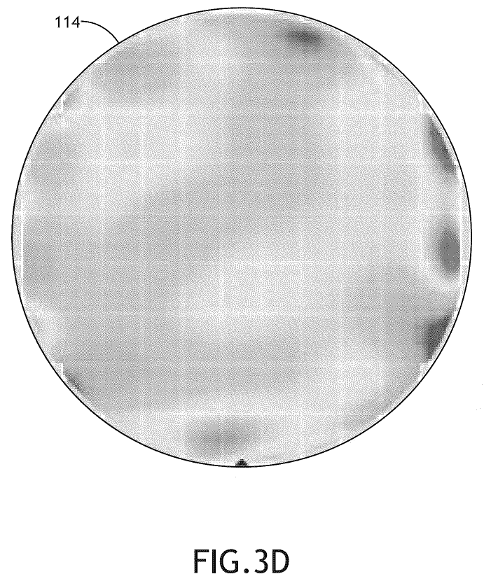

FIGS. 3A-3D depict an example of determining the modeled correction 114 with the model terms 115 from the metrology measurements 104, in accordance with one or more embodiments of the present disclosure. In this example, the metrology measurements 104 are from eight of the samples 106, although this is not intended to be limiting. In this example, the metrology measurements 104 are critical dimensions at 316 sampling locations across each of the eight of the samples 106.

In this example, the controller 108 selects the modeled correction 114 as a Zernike model of the thirteenth order and selects the model terms 115 as Zernike polynomials. The possible number of the model terms 115 for the Zernike model of the thirteenth order is one-hundred and five polynomials.

In this example, the controller 108 cross-validates the value of the regularization parameter 116 across a range of possible values from about 0.004 to 4. The controller 108 cross-validates the regularization parameter 116 across the range to determine the model terms 115 and a root mean square error associated with the model terms 115. The value of the regularization parameter 116 and the model terms 115 which minimize the root mean square error is selected. In this example, the controller 108 selects the model terms 115 as nineteen of the possible one-hundred and five polynomials. The model terms 115 of Z₀⁰, Z₁¹, Z₃⁻³, Z₃³, Z₄⁻⁴, Z₄⁻², Z₄⁴, Z₇⁷, Z₇⁻¹, Z₇¹, Z₇⁷, Z₈⁴, Z₉³, Z₉⁷, Z₁₀⁻¹⁰, Z₁₀², Z₁₀⁸, Z₁₂⁻¹², Z₁₂⁻¹⁰ are selected, although this is not intended to be limiting. The controller 108 may identify the model terms 115 as important to describe the signature of the metrology measurements 104. The model terms 115 may then be used to generate the modeled correction 114. This example illustrates how the controller 108 may use the model terms 115 with a high order (e.g., thirteenth order) to generate the modeled correction 114 without requiring many sampling points (e.g., eight samples).

As used throughout the present disclosure, the term “wafer” generally refers to a substrate formed of a semiconductor or non-semiconductor material. For example, a semiconductor or non-semiconductor material include, but are not limited to, monocrystalline silicon, gallium arsenide, and indium phosphide. A wafer may include one or more layers. For example, such layers may include, but are not limited to, a resist, a dielectric material, a conductive material, and a semiconductive material. Many different types of such layers are known in the art, and the term wafer as used herein is intended to encompass a wafer on which all types of such layers may be formed.

As used throughout the present disclosure, the term “substrate” generally refers to a substrate formed of a semiconductor or non-semiconductor material (e.g., thin filmed glass, or the like). For example, a semiconductor or non-semiconductor material may include, but is not limited to, monocrystalline silicon, gallium arsenide, indium phosphide, or a glass material. A substrate may include one or more layers. For example, such layers may include, but are not limited to, a resist (including a photoresist), a dielectric material, a conductive material, and a semiconductive material. Many different types of such layers are known in the art, and the term sample as used herein is intended to encompass a substrate on which all types of such layers may be formed. One or more layers formed on a substrate may be patterned or un-patterned. For example, a substrate may include a plurality of dies, each having repeatable patterned features. Formation and processing of such layers of material may ultimately result in completed devices. Many different types of devices may be formed on a substrate, and the term substrate as used herein is intended to encompass a substrate on which any type of device known in the art is being fabricated. Further, for the purposes of the present disclosure, the term substrate and wafer should be interpreted as interchangeable. In addition, for the purposes of the present disclosure, the terms patterning device, mask, and reticle should be interpreted as interchangeable.

For the purposes of the present disclosure, the term “registration measurement,” and the like may mean a measurement between two structures. For example, a registration measurement may mean a distance between two structures as projected onto two planes along a direction (e.g., X-direction, Y-direction). For example, such a direction may be orthogonal to a depth direction through layers of a sample. In this regard, a registration measurement may be the projected “X component” of a vector between two structures. For example, a registration measurement may be based on a single image where both structures are within the field of view of the image and a distance between structures in the image may be used to derive the registration measurement between the structures. In another example, a registration measurement is acquired as follows: first, imaging a position of a respective structure; then, moving the sample relative to the metrology sub-system by a precisely known distance; and finally, imaging a different structure. The positions (e.g., center positions) of the structures in the images and the known distance the sample was moved may be used to acquire the registration measurement between the structures. In another example, registration measurements may be mathematically determined between three or more structures using two or more registration measurements. For instance, the X components of a registration measurement between a first and second structure, and a registration measurement between the second structure and a third structure may be combined to determine the X component registration measurement between the first and third structure. It should be noted that examples of registration measurements in the present disclosure are provided for illustrative purposes and should not be interpreted as limiting, and any number of registration measurements (whether based on other registration measurements or not) to any number and type of structures may be combined to determine registration measurements between various structures.

The controller 108 may include one or more controllers housed in a common housing or within multiple housings. In this way, any controller or combination of controllers may be separately packaged as a module suitable for integration into a system. Further, the controllers may analyze data and feed the data to additional components within the system or external to the system.

The processors 110 of the controller 108 may be communicatively coupled to memory 112, where the processors 110 may be configured to execute a set of program instructions maintained in memory 112, and the set of program instructions may be configured to cause the processors 110 to carry out various functions and steps of the present disclosure.

It is noted herein that the one or more components of metrology system 100 may be communicatively coupled to the various other components of metrology system 100 in any manner known in the art. For example, the processors 110 may be communicatively coupled to each other and other components via a wireline (e.g., copper wire, fiber optic cable, and the like) or wireless connection (e.g., RF coupling, IR coupling, WiMax, Bluetooth, 3G, 4G, 4G LTE, 5G, and the like). By way of another example, the controller 108 may be communicatively coupled to one or more components of metrology system 100 via any wireline or wireless connection known in the art.

The processors 110 may include any one or more processing elements known in the art. In this sense, the processors 110 may include any microprocessor-type device configured to execute software algorithms and/or instructions. In embodiments, the processors 110 may consist of a desktop computer, mainframe computer system, workstation, image computer, parallel processor, or other computer system (e.g., networked computer) configured to execute a program configured to operate the metrology system 100, as described throughout the present disclosure. It should be recognized that the steps described throughout the present disclosure may be carried out by a single computer system or, alternatively, multiple computer systems. Furthermore, it should be recognized that the steps described throughout the present disclosure may be carried out on any one or more of the processors 110. In general, the term “processor” may be broadly defined to encompass any device having one or more processing elements, which execute program instructions from memory 112. Moreover, different subsystems of the metrology system 100 (e.g., metrology sub-system 102, controller 108, user interface, and the like) may include processor or logic elements suitable for carrying out at least a portion of the steps described throughout the present disclosure. Therefore, the above description should not be interpreted as a limitation on the present disclosure but merely an illustration.

The memory 112 may include any storage medium known in the art suitable for storing program instructions executable by the processors 110 and the data received from the metrology system 100. For example, the memory 112 may include a non-transitory memory medium. For instance, the memory 112 may include, but is not limited to, a read-only memory (ROM), a random-access memory (RAM), a magnetic or optical memory (e.g., disk), a magnetic tape, a solid-state drive, and the like. It is further noted that the memory 112 may be housed in a common controller housing with the processors 110. In an alternative embodiment, the memory 112 may be located remotely with respect to the physical location of the processors 110, controller 108, and the like. In another embodiment, the memory 112 may maintain program instructions for causing the processors 110 to carry out the various steps described through the present disclosure.

A user interface may be communicatively coupled to the controller 108. The user interface may include, but is not limited to, one or more desktops, tablets, smartphones, smart watches, or the like. The user interface may include a display used to display data of the metrology system 100 to a user. The display of the user interface may include any display known in the art. For example, the display may include, but is not limited to, a liquid crystal display (LCD), an organic light-emitting diode (OLED) based display, or a CRT display. Any display device capable of integration with a user interface is suitable for implementation in the present disclosure. A user may input selections and/or instructions responsive to data displayed to the user via a user input device of the user interface.

In the case of a control algorithm, one or more program instructions or methods may be configured to operate via proportional control, feedback control, feedforward control, integral control, proportional-derivative (PD) control, proportional-integral (PI) control, proportional-integral-derivative (PID) control, or the like.

All of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period. For example, the memory may be random access memory (RAM), and the results may not necessarily persist indefinitely in the memory.

The results may be stored on a system (e.g., external controller and memory such as external server) that is external to the metrology sub-system 102. Examples of such systems include systems configured to compile and reduce data (e.g., results) to generate relevant root cause and yield analysis information. For instance, software (e.g., OVALiS software) on external systems may support on-product process optimization, diagnostics, monitoring and control for lithography and other patterning steps that are critical to IC manufacturing. Further, 5D Analyzer advanced data analysis and patterning control software may be used to provide for an extendible, open architecture that accepts data from a wide range of metrology and process tools to enable advanced analysis, characterization, and real-time control of fab-wide process variations.

It is further contemplated that each of the embodiments of the methods described above may include any other step(s) of any other method(s) described herein. In addition, each of the embodiments of the method described above may be performed by any of the systems described herein.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mixable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A metrology system comprising:
a metrology sub-system; and
a controller communicatively coupled to the metrology sub-system, wherein the controller includes one or more processors configured to execute program instructions stored in memory, the program instructions configured to cause the one or more processors to:
receive a plurality of metrology measurements of a sample;
select a value of a regularization parameter by cross-validating the regularization parameter across a range of possible values using the plurality of metrology measurements; and
generate a modeled correction based on the plurality of metrology measurements and the value of the regularization parameter using a regression that reduces a residual between the modeled correction and the plurality of metrology measurements, wherein the modeled correction is defined by a plurality of model terms, wherein the plurality of model terms comprises a sub-set of possible model terms up to a maximum order, wherein the regularization parameter controls a number of the plurality of model terms which are selected as the sub-set.

2. The metrology system of claim 1, wherein the plurality of metrology measurements comprise at least one of an overlay or one or more critical dimensions.

3. The metrology system of claim 1, wherein cross-validating the regularization parameter comprises using the regression to determine a plurality of possible model terms for each of the range of possible values and evaluating the possible model terms against the plurality of metrology measurements.

4. The metrology system of claim 1, wherein the controller is configured to select the value of the regularization parameter which minimizes a root mean square error between the possible model terms and the plurality of metrology measurements.

5. The metrology system of claim 1, the controller is configured to cross-validate the value of the regularization parameter across the sample.

6. The metrology system of claim 1, wherein the sample is one of a plurality of samples, wherein the plurality of metrology measurements are of the plurality of samples, wherein the controller is configured to cross-validate the regularization parameter across the plurality of samples.

7. The metrology system of claim 6, wherein the controller is configured to generate the modeled correction from a sliding window of the plurality of metrology measurements over time.

8. The metrology system of claim 6, wherein the controller is configured to weigh the plurality of metrology measurements using a weighted average when cross-validating the value of the regularization parameter across the plurality of samples.

9. The metrology system of claim 1, wherein the modeled correction is one of a linear model or a polynomial model.

10. The metrology system of claim 9, wherein the modeled correction is the polynomial model, wherein the modeled correction comprises at least one of a Zernike polynomial or a Legendre polynomial.

11. The metrology system of claim 1, wherein the regression is a lasso regression.

12. The metrology system of claim 1, wherein the maximum order is between three and thirteen.

13. The metrology system of claim 1, wherein the modeled correction comprises at least one of a dose correction, a focus correction, or an overlay correction.

14. The metrology system of claim 1, wherein the controller is configured to enforce using one or more specific model terms of the possible model terms during the regression thereby ensuring the one or more specific model terms are included in the modeled correction.

15. The metrology system of claim 1, wherein the regularization parameter is added as a penalty term to the residual.

16. The metrology system of claim 1, wherein cross-validating comprises at least one of leave-one-out cross-validation, K-fold cross-validation, or hold-out cross-validation.

17. The metrology system of claim 1, wherein the metrology sub-system is configured to generate the plurality of metrology measurements of the sample, wherein the controller is configured to receive the plurality of metrology measurements from the metrology sub-system.

18. The metrology system of claim 1, wherein the controller is configured to control a process tool based on the modeled correction with at least one of a feedback control or a feedforward control.

19. A metrology system comprising:
a controller including one or more processors configured to execute program instructions stored in memory, the program instructions configured to cause the one or more processors to:
receive a plurality of metrology measurements of a sample;
select a value of a regularization parameter by cross-validating the regularization parameter across a range of possible values using the plurality of metrology measurements; and
generate a modeled correction based on the plurality of metrology measurements and the value of the regularization parameter using a regression that reduces a residual between the modeled correction and the plurality of metrology measurements, wherein the modeled correction is defined by a plurality of model terms, wherein the plurality of model terms comprises a sub-set of possible model terms up to a maximum order, wherein the regularization parameter controls a number of the plurality of model terms which are selected as the sub-set.

20. The metrology system of claim 19, wherein the controller is configured to control a process tool based on the modeled correction with at least one of a feedback control or a feedforward control.

21. A method comprising:
receiving a plurality of metrology measurements of a sample;
selecting a value of a regularization parameter by cross-validating the regularization parameter across a range of possible values using the plurality of metrology measurements; and
generating a modeled correction based on the plurality of metrology measurements and the value of the regularization parameter using a regression that reduces a residual between the modeled correction and the plurality of metrology measurements, wherein the modeled correction is defined by a plurality of model terms, wherein the plurality of model terms comprises a sub-set of possible model terms up to a maximum order, wherein the regularization parameter controls a number of the plurality of model terms which are selected as the sub-set.

22. The method of claim 21, comprising controlling a process tool based on the modeled correction with at least one of a feedback control or a feedforward control.
